(19) United States
(12) Patent Application Publication
(10) Pub. No.: US 2026/0150324 A1
(43) Pub. Date: May 28, 2026

(54) SEMICONDUCTOR DEVICE

(71) Applicant: KABUSHIKI KAISHA TOSHIBA, Tokyo (JP)

(72) Inventors: Aya SHINDOME, Yokohama (JP); Hiroshi ONO, Setagaya (JP); Miyoko SHIMADA, Yokohama (JP); Mariko SHIMIZU, Setagaya (JP); Yosuke KAJIWARA, Yokohama (JP)

(73) Assignee: KABUSHIKI KAISHA TOSHIBA, Tokyo (JP)

(21) Appl. No.: 19/254,823

(22) Filed: Jun. 30, 2025

(30) Foreign Application Priority Data
Nov. 26, 2024 (JP) 2024-205679

(51) Int. Cl. H10D 30/47; H10D 62/85; H10D 64/27

(52) U.S. Cl. CPC H10D 30/475; H10D 62/8503; H10D 64/411

(57) ABSTRACT

According to one embodiment, a semiconductor device includes first to third electrodes, a semiconductor member, and a first insulating member. The semiconductor member includes first and semiconductor regions. The first semiconductor region includes Alₓ₁Ga₁₋ₓ₁N (0≤x1<1). The second semiconductor region includes Alₓ₂Ga₁₋ₓ₂N (x1<x2≤1). The third partial region of the first semiconductor member includes first and second portions. The fourth partial region of the first semiconductor member includes facing portion facing the first electrode portion of the third electrode. The first portion and the facing portion do not include a p-type impurity, or a first concentration of the p-type impurity in the first portion is not less than 0.2 times and not more than 5 times a concentration of the p-type impurity in the facing portion.

### CROSS-REFERENCE TO RELATED APPLICATIONS

This application is based upon and claims the benefit of priority from Japanese Patent Application No. 2024-205679, filed on Nov. 26, 2024; the entire contents of which are incorporated herein by reference.

### FIELD

Embodiments described herein relate generally to a semiconductor device.

### BACKGROUND

For example, in semiconductor devices such as transistors, improvements in characteristics are desired.

### BRIEF DESCRIPTION OF THE DRAWINGS

FIG. 1 is a schematic cross-sectional view illustrating a semiconductor device according to a first embodiment;

FIG. 2 is a graph illustrating the characteristics of a semiconductor device;

FIG. 3 is a schematic cross-sectional view illustrating a semiconductor device according to the first embodiment;

FIG. 4 is a schematic cross-sectional view illustrating a semiconductor device according to the first embodiment; and

FIG. 5 is a schematic cross-sectional view illustrating a semiconductor device according to a second embodiment.

### DETAILED DESCRIPTION

According to one embodiment, a semiconductor device includes a first electrode, a second electrode, a third electrode, a semiconductor member, and a first insulating member. The third electrode includes a first electrode portion. The first electrode portion is provided between the first electrode and the second electrode in a first direction from the first electrode to the second electrode. At least a part of the first insulating member is provided between the third electrode and the semiconductor member. The semiconductor member includes a first semiconductor region and a second semiconductor region. The first semiconductor region includes Alₓ₁Ga₁₋ₓ₁N (0≤x1<1). The first semiconductor region includes a first partial region, a second partial region, a third partial region, a fourth partial region, and a fifth partial region. A second direction from the first partial region to the first electrode crosses the first direction. A direction from the second partial region to the second electrode is along the second direction. A direction from the third partial region to the first electrode portion is along the second direction. A fourth position in the first direction of the fourth partial region is between a first position in the first direction of the first partial region and a third position in the first direction of the third partial region. A fifth position in the first direction of the fifth partial region is between the third position and a second position in the first direction of the second partial region. The second semiconductor region includes Alₓ₂Ga₁₋ₓ₂N (x1<x2≤1). The second semiconductor region includes a first semiconductor portion and a second semiconductor portion. A direction from the fourth partial region to the first semiconductor portion is along the second direction. A direction from the fifth partial region to the second semiconductor portion is along the second direction. At least a part of the first electrode portion is between the first semiconductor portion and the second semiconductor portion in the first direction. The second semiconductor region includes a first semiconductor face and a second semiconductor face. The second semiconductor face faces the first semiconductor region. The second semiconductor face is between the first semiconductor region and the first semiconductor face in the second direction. The third partial region includes a first portion and a second portion. A first portion position of the first portion in the first direction is between the fourth position and a second portion position of the second portion in the first direction. The first portion includes a first face facing the first electrode portion in the second direction. The second portion includes a second face facing the first electrode portion in the second direction. A first distance along the second direction between the first face and the second semiconductor face is shorter than a second distance along the second direction between the second face and the second semiconductor face. The fourth partial region includes a facing portion facing the first electrode portion in the first direction. The first portion and the facing portion do not include a p-type impurity, or a first concentration of the p-type impurity in the first portion is not less than 0.2 times and not more than 5 times a facing portion concentration of the p-type impurity in the facing portion.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

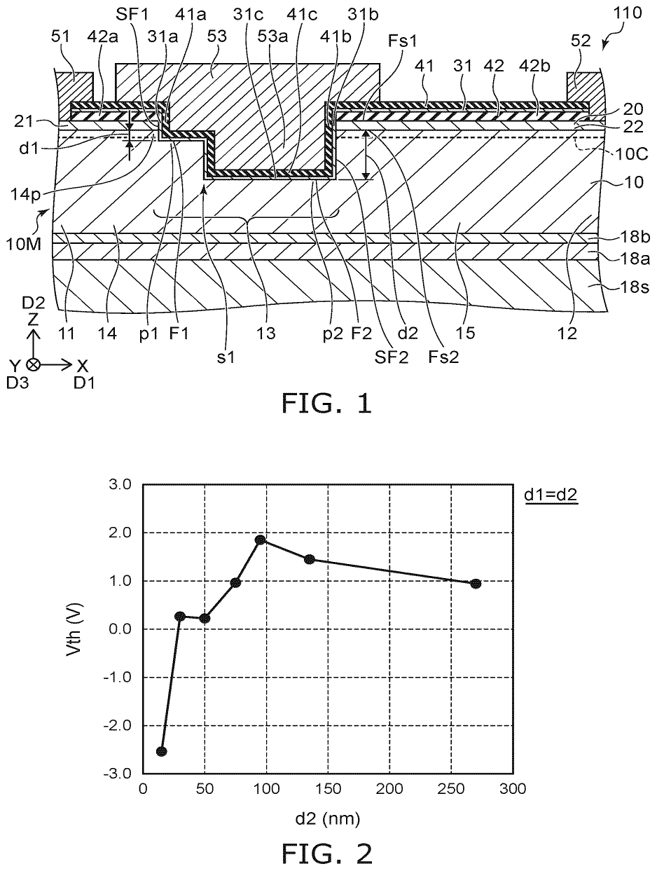

FIG. 1 is a schematic cross-sectional view illustrating a semiconductor device according to a first embodiment.

As shown in FIG. 1, a semiconductor device 110 according to the embodiment includes a first electrode 51, a second electrode 52, a third electrode 53, a semiconductor member 10M, and a first insulating member 41.

A first direction D1 from the first electrode 51 to the second electrode 52 is defined as an X-axis direction. A direction perpendicular to the X-axis direction is defined as a Z-axis direction. A direction perpendicular to the X-axis direction and the Z-axis direction is defined as a Y-axis direction.

The third electrode 53 includes a first electrode portion 53a. The first electrode portion 53a is provided between the first electrode 51 and the second electrode 52 in the first direction D1.

At least a part of the first insulating member 41 is provided between the third electrode 53 and the semiconductor member 10M.

The semiconductor member 10M includes a first semiconductor region 10 and a second semiconductor region 20. The first semiconductor region 10 includes Alₓ₁Ga₁₋ₓ₁N (0≤x1<1). The composition ratio x1 may be, for example, not less than 0 and not more than 0.13. The first semiconductor region 10 includes, for example, GaN.

The first semiconductor region 10 includes a first partial region 11, a second partial region 12, a third partial region 13, a fourth partial region 14, and a fifth partial region 15. A second direction D2 from the first partial region 11 to the first electrode 51 crosses the first direction D1. The second direction D2 may be, for example, the Z-axis direction. A direction from the second partial region 12 to the second electrode 52 is along the second direction D2. A direction from the third partial region 13 to the first electrode portion 53a is along the second direction D2.

The region overlapping the first electrode 51 in the second direction D2 corresponds to the first partial region 11. The region overlapping the second electrode 52 in the second direction D2 corresponds to the second partial region 12. The region overlapping the first electrode portion 53a in the second direction D2 corresponds to the third partial region 13.

A fourth position in the first direction D1 of the fourth partial region 14 is between a first position in the first direction D1 of the first partial region 11 and a third position in the first direction D1 of the third partial region 13. A fifth position in the first direction D1 of the fifth partial region 15 is between the third position and a second position in the first direction D1 of the second partial region 12.

The second semiconductor region 20 includes Alₓ₂Ga₁₋ₓ₂N (x1<x2≤1). The composition ratio x2 may be, for example, not less than 0.15 and not more than 0.35. The second semiconductor region 20 includes, for example, AlGaN.

The second semiconductor region 20 includes a first semiconductor portion 21 and a second semiconductor portion 22. A direction from the fourth partial region 14 to the first semiconductor portion 21 is along the second direction D2. A direction from the fifth partial region 15 to the second semiconductor portion 22 is along the second direction D2.

At least a part of the first electrode portion 53a is between the first semiconductor portion 21 and the second semiconductor portion 22 in the first direction D1. A part of the first electrode portion 53a may be provided between the fourth partial region 14 and the fifth partial region 15 in the first direction D1.

The second semiconductor region 20 includes a first semiconductor face Fs1 and a second semiconductor face Fs2. The second semiconductor face Fs2 faces the first semiconductor region 10. The second semiconductor face Fs2 is located between the first semiconductor region 10 and the first semiconductor face Fs1 in the second direction D2. The first semiconductor face Fs1 is, for example, the upper face.

The third partial region 13 includes a first portion p1 and a second portion p2. A position of the first portion p1 in the first direction D1 (first portion position) is between the fourth position of the fourth partial region 14 in the first direction D1 and the position of the second portion p2 in the first direction D1 (second portion position).

The first portion p1 includes a first face F1. The first face F1 faces the first electrode portion 53a in the second direction D2. The second portion p2 includes a second face F2. The second face F2 faces the first electrode portion 53a in the second direction D2.

A distance along the second direction D2 between the first face F1 and the second semiconductor face Fs2 is defined as a first distance d1. A distance along the second direction D2 between the second face F2 and the second semiconductor face Fs2 is defined as a second distance d2. The first distance d1 is shorter than the second distance d2. With the second semiconductor face Fs2 as a reference, the first face F1 is shallower than the second face F2.

The fourth partial region 14 includes a facing portion 14p. The facing portion 14p faces the first electrode portion 53a in the first direction D1.

In the embodiment, the first portion p1 and the facing portion 14p do not include p-type impurity. Alternatively, a concentration of p-type impurity in the first portion p1 is substantially the same as a concentration of p-type impurity in the facing portion 14p. For example, a first concentration of p-type impurity in the first portion p1 is not less than 0.2 times and not more than 5 times a facing portion concentration of p-type impurity in the facing portion 14p. For example, the first portion p1 and the facing portion 14p are i-GaN.

The second portion p2 does not include p-type impurity. Alternatively, the first concentration is not less than 0.2 times and not more than 5 times a second concentration of the p-type impurity in the second portion p2. For example, the second portion p2 is i-GaN.

In the semiconductor device 110, current flowing between the first electrode 51 and the second electrode 52 can be controlled by a potential of the third electrode 53. The potential of the third electrode 53 is, for example, a potential based on a potential of the first electrode 51. The first electrode 51 functions, for example, as one of a source electrode and a drain electrode. The second electrode 52 functions, for example, as the other of the source electrode and the drain electrode. The third electrode 53 functions, for example, as a gate electrode. The semiconductor device 110 is, for example, a transistor.

The first semiconductor region 10 includes a portion facing the second semiconductor region 20. A carrier region 10C is formed in this portion. The carrier region 10C is, for example, a two-dimensional electron gas. The semiconductor device 110 is, for example, a HEMT (High Electron Mobility Transistor).

As already explained, at least a part of the first electrode portion 53a is between the first semiconductor portion 21 and the second semiconductor portion 22 in the first direction D1. The third electrode 53 is a recessed gate electrode. For example, a high threshold voltage is obtained. For example, normally-off operation is obtained.

As described above, in the embodiment, the first distance d1 is shorter than the second distance d2. This allows, for example, a low on-resistance to be obtained while maintaining a high threshold voltage.

For example, in a reference example, the first distance d1 is the same as the second distance d2. In such a reference example, if the first distance d1 (i.e., the second distance d2) is increased, the threshold voltage is high but the on-resistance is high. On the other hand, if the first distance d1 (i.e., the second distance d2) is decreased, a low on-resistance is obtained but the threshold voltage is reduced.

In contrast, in the embodiment, the second distance d2 is long in the second portion p2 close to the second electrode 52. This results in a high threshold voltage. On the other hand, the first distance d1 is short in the first portion p1 close to the first electrode 51. This results in a low on-resistance. In the embodiment, a high threshold voltage and a low on-resistance are obtained. According to the embodiment, a semiconductor device with improved characteristics can be provided.

In the embodiment, a distance between the first electrode 51 and the third electrode 53 in the first direction D1 is shorter than a distance between the third electrode 53 and the second electrode 52 in the first direction D1. The first electrode 51 is, for example, a source electrode. The second electrode 52 is a drain electrode.

The first electrode 51, the second electrode 52, and the third electrode 53 may extend along a third direction D3. The third direction D3 crosses a plane including the first direction D1 and the second direction D2. The third direction D3 may be, for example, the Y-axis direction.

In the embodiment, the first concentration of the p-type impurity in the first portion p1 may be, for example, less than 1×10¹⁷ cm⁻³. The first concentration may be, for example, less than 1×10¹⁶ cm⁻³. The second concentration of the p-type impurity in the second portion p2 may be, for example, less than 1×10¹⁷ cm⁻³. The second concentration may be, for example, less than 1×10¹⁶ cm⁻³. The low concentration of the impurity in these portions (first semiconductor region 10) may, for example, provide a high carrier concentration. This may, for example, provide a lower on-resistance.

As shown in FIG. 1, the semiconductor device 110 may include a first compound member 31. The first compound member 31 includes Al_{z1}Ga_{1-z1}N (x2<z1≤1). The composition ratio z1 may be, for example, not less than 0.8 and not more than 1. The first compound member 31 includes, for example, AlN.

At least a part of the first compound member 31 is provided between the facing portion 14p and the first insulating member 41, between the first portion p1 and the first insulating member 41, and between the second portion p2 and the first insulating member 41.

For example, the first portion p1 includes a portion facing the first compound member 31. The carrier region 10C may be formed in this portion. For example, the second portion p2 includes a portion facing the first compound member 31. The carrier region 10C may be formed in this portion. These regions make it easier to obtain a low on-resistance.

For example, if at least one of the first portion p1 and the second portion p2 includes p-type impurity, it is difficult to form the above-mentioned carrier region 10C. As the first portion p1 and the second portion p2 are substantially free of p-type impurity, a low on-resistance is effectively obtained.

For example, a low concentration of p-type impurity in the facing portion 14p results in a high carrier concentration in the current path that includes the facing portion 14p. This results in a low on-resistance.

FIG. 2 is a graph illustrating the characteristics of a semiconductor device.

FIG. 2 illustrates experimental results relating to the characteristics of a reference example in which the first distance d1 is the same as the second distance d2. The horizontal axis is the second distance d2 (i.e., the first distance d1). The vertical axis is the threshold voltage. As shown in FIG. 2, when the second distance d2 is 100 nm or more, a high threshold voltage Vth is obtained. When the second distance d2 is less than 75 nm, the threshold voltage Vth is low. When the second distance d2 is less than 75 nm, it is considered that a current path is generated.

From the results in FIG. 2, it is considered that when the first distance d1 is less than 75 nm, low resistance is obtained in the current path in the first portion p1.

In the embodiment, it is preferable that the first distance d1 is, for example, less than 75 nm. A low on-resistance is easily and stably obtained. It is preferable that the second distance d2 is, for example, 100 nm or more. A high threshold voltage Vth is easily and stably obtained. The second distance d2 may be, for example, 130 nm or more.

For example, the first distance d1 may be equal to or less than ½ of the second distance d2.

The first portion p1 may face, for example, the end (first end) of the first electrode portion 53a on the side of the first electrode 51. The second portion p2 may face the end (second end) of the first electrode portion 53a on the side of the second electrode 52.

For example, the first face F1 may be along the first direction D1. The second face F2 may be along the first direction D1. The first face F1 and the second face F2 may be along a plane (X-Y plane) perpendicular to the second direction D2, for example. A low resistance is easily obtained in a current path including the first portion p1 and the second portion p2.

As shown in FIG. 1, the third partial region 13 may include a first step s1 between the first portion p1 and the second portion p2. By discontinuously changing the depth, for example, a high threshold voltage and a low on-resistance are easily and stably obtained.

As shown in FIG. 1, the first insulating member 41 may include a first insulating region 41a, a second insulating region 41b, and a third insulating region 41c. At least a part of the first insulating region 41a is located between the first semiconductor portion 21 and the first electrode portion 53a. At least a part of the second insulating region 41b is located between the first electrode portion 53a and the second semiconductor portion 22. The third insulating region 41c is located between the third partial region 13 and the first electrode portion 53a in the second direction D2.

The first compound member 31 may include a first compound region 31a, a second compound region 31b, and a third compound region 31c. At least a part of the first compound region 31a is located between the first semiconductor portion 21 and the first insulating region 41a. At least a part of the second compound region 31b is located between the second insulating region 41b and the second semiconductor portion 22. The third compound region 31c is located between the third partial region 13 and the third insulating region 41c in the second direction D2.

The semiconductor device 110 may further include a second insulating member 42. The second insulating member 42 includes a first insulating portion 42a and a second insulating portion 42b. The first insulating portion 42a is located between the first semiconductor portion 21 and a part of the first insulating member 41 in the second direction D2. The second insulating portion 42b is located between the second semiconductor portion 22 and another part of the first insulating member 41 in the second direction D2. The second insulating member 42 functions, for example, as a passivation film. The second insulating member 42 may include, for example, Si and at least one selected from the group consisting of oxygen and nitrogen.

The first insulating member 41 may include, for example, Si and at least one selected from the group consisting of oxygen and nitrogen. The first insulating member 41 may include, for example, silicon oxide. Good insulation properties are obtained.

In the embodiment, the p-type impurity includes, for example, at least one selected from the group consisting of Mg, Zn, and Be. The p-type impurity includes, for example, Mg.

As shown in FIG. 1, the facing portion 14p includes a first side face SF1 facing the first electrode portion 53a. An angle (first angle) between the first side face SF1 and the first face F1 may be not less than 80 degrees and not more than 100 degrees. For example, the first side face SF1 may be substantially perpendicular to the first face F1.

The fifth partial region 15 includes a second side face SF2 facing the first electrode portion 53a in the first direction D1. An angle (second angle) between the second side face SF2 and the second face F2 may be not less than 80 degrees and not more than 100 degrees. For example, the second side face SF2 may be substantially perpendicular to the second face F2. When the second angle is close to 90 degrees, for example, a high threshold voltage Vth is easily obtained.

As shown in FIG. 1, the semiconductor device 110 may include a base 18s. The base 18s may be, for example, a silicon substrate. The semiconductor device 110 may include a nitride layer 18a. The nitride layer 18a is provided between the base 18s and the first semiconductor region 10. The nitride layer 18a includes, for example, Al, Ga, and N. The nitride layer 18a is, for example, a buffer layer. The nitride layer 18a is provided on the base 18s. The first semiconductor region 10 is provided on the nitride layer 18a. The second semiconductor region 20 is provided on the first semiconductor region 10. For example, the first electrode 51, the second electrode 52, and the third electrode 53 are provided on the first semiconductor region 10.

The semiconductor member 10M may include an intermediate layer 18b including carbon (C). The intermediate layer 18b is provided between the nitride layer 18a and the first semiconductor region 10. The intermediate layer 18b may have, for example, the same composition as the first semiconductor region 10. The intermediate layer 18b may be, for example, a GaN layer including carbon. For example, high insulation properties are easily obtained. The carbon concentration in the intermediate layer 18b may be, for example, not less than 1×10¹⁸ cm⁻³ and not more than 1×10²¹ cm⁻³.

The first semiconductor region 10 may include carbon. The carbon concentration in the first semiconductor region 10 is lower than the carbon concentration in the intermediate layer 18b. The carbon concentration in the first semiconductor region 10 may be, for example, not less than 1×10¹⁶ cm⁻³ and not more than 5×10¹⁷ cm⁻³. The Mg concentration in the first semiconductor region 10 is lower than the carbon concentration in the first semiconductor region 10. The Mg concentration in the first semiconductor region 10 may be ⅕ or less of the carbon concentration in the first semiconductor region 10.

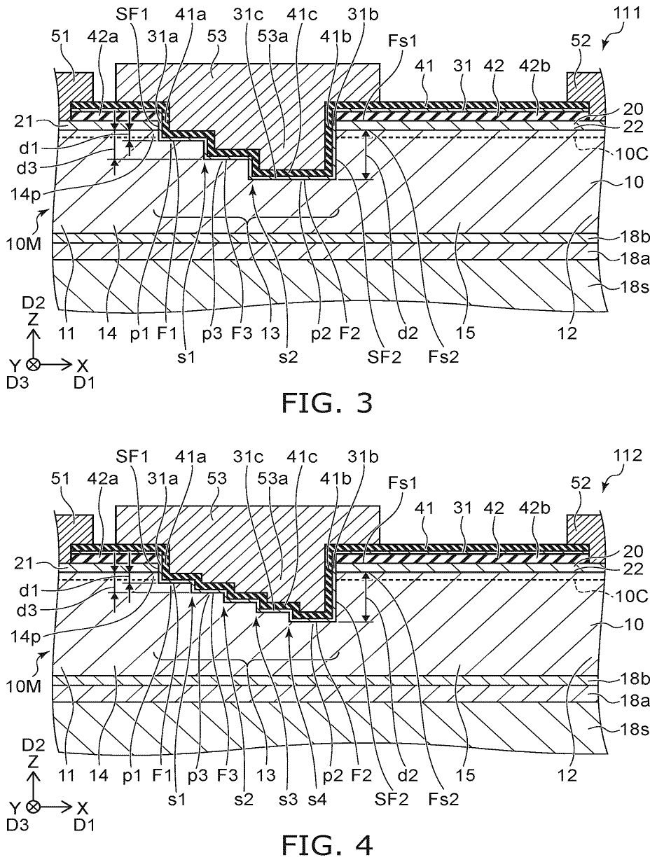

FIG. 3 is a schematic cross-sectional view illustrating a semiconductor device according to the first embodiment.

As shown in FIG. 3, in a semiconductor device 111 according to the embodiment, the first semiconductor region 10 includes a third portion p3. Except for this, the configuration of the semiconductor device 111 may the same as the configuration of the semiconductor device 110.

In the semiconductor device 111, the third partial region 13 further includes the third portion p3. A position of the third portion p3 in the first direction D1 (third portion position) is between the position of the first portion p1 in the first direction D1 (first portion position) and the position of the second portion p2 in the first direction D1 (second portion position).

The third portion p3 includes a third face F3 facing the first electrode portion 53a in the second direction D2. A distance along the second direction D2 between the third face F3 and the second semiconductor face Fs2 is defined as a third distance d3. The third distance d3 is between the first distance d1 and the second distance d2.

For example, the third portion p3 does not include p-type impurity. Alternatively, the first concentration is not less than 0.2 times and not more than 5 times a third concentration of p-type impurity in the third portion p3. Thus, the third partial region 13 may include three or more faces.

The third partial region 13 may include a second step s2 between the third portion p3 and the second portion p2. The third partial region 13 may include two or more steps. By discontinuously changing the depth, for example, it is easier to stably obtain a high threshold voltage and a low on-resistance.

FIG. 4 is a schematic cross-sectional view illustrating a semiconductor device according to the first embodiment.

As shown in FIG. 4, in a semiconductor device 112 according to the embodiment, the first semiconductor region 10 includes a third step s3 and the like. Except for this, the configuration of the semiconductor device 112 may be the same as the configuration of the semiconductor device 111.

In the semiconductor device 112, the third partial region 13 may include a third step s3 and a fourth step s4, etc.

The above-mentioned first portion p1 and second portion p2, etc., may be formed by processing the semiconductor member 10M using multiple masks. The multiple steps may be formed, for example, by repeating a process that includes processing the semiconductor member 10M using a mask and retracting the mask.

### Second Embodiment

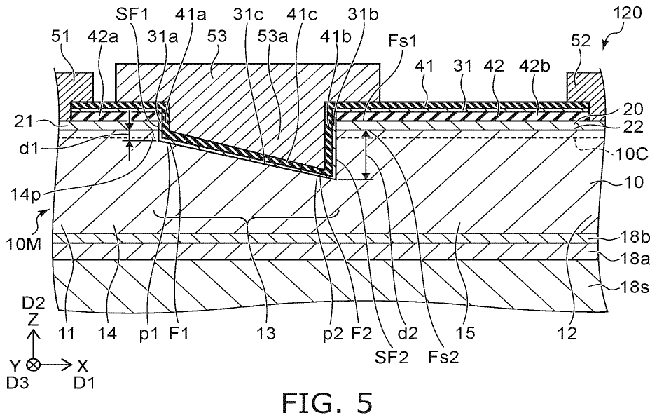

FIG. 5 is a schematic cross-sectional view illustrating a semiconductor device according to a second embodiment.

As shown in FIG. 5, in a semiconductor device 120 according to the embodiment, the first face F1 and the second face F2 are inclined with respect to the second direction D2. Except for this, the configuration of the semiconductor device 120 may be the same as the configuration of the semiconductor device 110 according to the first embodiment.

In the semiconductor device 120, at least one of the first face F1 or the second face F2 may be inclined with respect to the first direction D1. In the semiconductor device 120, the first distance d1 is also shorter than the second distance d2. A high threshold voltage and a low on-resistance are obtained. According to the embodiment, a semiconductor device capable of improving characteristics can be provided.

In the embodiment, information regarding the shape of the semiconductor region is obtained, for example, from an electron microscope image. Information regarding the composition and element concentration is obtained, for example, from EDX (Energy Dispersive X-ray Spectroscopy) or SIMS (Secondary Ion Mass Spectrometry). Information regarding the composition may be obtained, for example, from reciprocal space mapping.

The embodiments may include the following Technical proposals.

### (Technical Proposal 1)

A semiconductor device, comprising:
a first electrode;
a second electrode;
a third electrode including a first electrode portion, the first electrode portion being provided between the first electrode and the second electrode in a first direction from the first electrode to the second electrode;
a semiconductor member; and
a first insulating member,
at least a part of the first insulating member being provided between the third electrode and the semiconductor member,
the semiconductor member including a first semiconductor region and a second semiconductor region,
the first semiconductor region including Alₓ₁Ga₁₋ₓ₁N (0≤x1<1),
the first semiconductor region including a first partial region, a second partial region, a third partial region, a fourth partial region, and a fifth partial region,
a second direction from the first partial region to the first electrode crossing the first direction,
a direction from the second partial region to the second electrode being along the second direction,
a direction from the third partial region to the first electrode portion being along the second direction,
a fourth position in the first direction of the fourth partial region being between a first position in the first direction of the first partial region and a third position in the first direction of the third partial region,
a fifth position in the first direction of the fifth partial region being between the third position and a second position in the first direction of the second partial region,
the second semiconductor region including Alₓ₂Ga₁₋ₓ₂N (x1<x2≤1),
the second semiconductor region including a first semiconductor portion and a second semiconductor portion,
a direction from the fourth partial region to the first semiconductor portion being along the second direction,
a direction from the fifth partial region to the second semiconductor portion being along the second direction,
at least a part of the first electrode portion being between the first semiconductor portion and the second semiconductor portion in the first direction,
the second semiconductor region including a first semiconductor face and a second semiconductor face, the second semiconductor face facing the first semiconductor region, the second semiconductor face being between the first semiconductor region and the first semiconductor face in the second direction,
the third partial region includes a first portion and a second portion,
a first portion position of the first portion in the first direction being between the fourth position and a second portion position of the second portion in the first direction,
the first portion including a first face facing the first electrode portion in the second direction,
the second portion including a second face facing the first electrode portion in the second direction,
a first distance along the second direction between the first face and the second semiconductor face being shorter than a second distance along the second direction between the second face and the second semiconductor face,
the fourth partial region including a facing portion facing the first electrode portion in the first direction,
the first portion and the facing portion not including a p-type impurity, or a first concentration of the p-type impurity in the first portion is not less than 0.2 times and not more than 5 times a facing portion concentration of the p-type impurity in the facing portion.

### (Technical Proposal 2)

The semiconductor device according to Technical proposal 1, wherein
the second portion does not include the p-type impurity, or the first concentration is not less than 0.2 times and not more than 5 times a second concentration of the p-type impurity in the second portion.

### (Technical Proposal 3)

The semiconductor device according to Technical proposal 2, wherein
the second concentration is less than 1×10¹⁷ cm⁻³.

### (Technical Proposal 4)

The semiconductor device according to any one of technical proposals 1-3, wherein
the first concentration is less than 1×10¹⁷ cm⁻³.

### (Technical Proposal 5)

The semiconductor device according to any one of technical proposals 1-4, further comprising:
a first compound member including Al_{z1}Ga_{1-z1}N (x2<z1≤1),
at least a part of the first compound member being provided between the facing portion and the first insulating member, between the first portion and the first insulating member, and between the second portion and the first insulating member.

### (Technical Proposal 6)

The semiconductor device according to any one of technical proposals 1-5, wherein
the first distance is less than 75 nm, and
the second distance is 100 nm or more.

### (Technical Proposal 7)

The semiconductor device according to any one of technical proposals 1-5, wherein
the first distance is equal to or less than ½ of the second distance.

### (Technical Proposal 8)

The semiconductor device according to any one of technical proposals 1-7, wherein
the first portion faces a first end of the first electrode portion on a side of the first electrode, and
the second portion faces a second end of the first electrode portion on a side of the second electrode.

### (Technical Proposal 9)

The semiconductor device according to any one of technical proposals 1-8, wherein
the first face is aligned along the first direction, and
the second face is aligned along the first direction.

### (Technical Proposal 10)

The semiconductor device according to any one of Technical proposals 1-8, wherein
at least one of the first face or the second face is inclined with respect to the first direction.

### (Technical Proposal 11)

The semiconductor device according to any one of Technical proposals 1-10, wherein
a distance between the first electrode and the third electrode along the first direction is shorter than a distance between the third electrode and the second electrode along the first direction.

### (Technical Proposal 12)

The semiconductor device according to any one of technical proposals 1-11, wherein
the third partial region includes a first step between the first portion and the second portion.

### (Technical Proposal 13)

The semiconductor device according to any one of Technical proposals 1-12, wherein
the third partial region further includes a third portion,
a third portion position in the first direction of the third portion is between the first portion position and the second portion position,
the third portion includes a third face facing the first electrode portion in the second direction, and
a third distance along the second direction between the third face and the first semiconductor face is between the first distance and the second distance.

### (Technical Proposal 14)

The semiconductor device according to Technical proposal 13, wherein
the third portion does not include the p-type impurity, or the first concentration is not less than 0.2 times and not more than 5 times a third concentration of the p-type impurity in the third portion.

### (Technical Proposal 15)

The semiconductor device according to Technical proposal 13 or 14, wherein
the third partial region includes a second step between the third portion and the second portion.

### (Technical Proposal 16)

The semiconductor device according to Technical proposal 15, wherein
the third partial region includes one or more steps provided between the second step and the second portion.

### (Technical Proposal 17)

The semiconductor device according to any one of Technical proposals 1-16, wherein
the p-type impurity includes at least one selected from the group consisting of Mg, Zn, and Be.

### (Technical Proposal 18)

The semiconductor device according to any one of technical proposals 1-17, wherein
the facing portion includes a first side face that faces the first electrode portion, and
a first angle between the first side face and the first face is not less than 80 degrees and not more than 100 degrees.

### (Technical Proposal 19)

The semiconductor device according to any one of Technical proposals 1-18, wherein
the fifth partial region includes a second side face that faces the first electrode portion in the first direction, and
a second angle between the second side face and the second face is not less than 80 degrees and not more than 100 degrees.

### (Technical Proposal 20)

The semiconductor device according to any one of Technical proposals 1-19, further comprising a second insulating member,
the second insulating member including a first insulating portion and a second insulating portion,
the first insulating portion being between the first semiconductor portion and a part of the first insulating member in the second direction, and
the second insulating portion being between the second semiconductor portion and another part of the first insulating member in the second direction.

According to the embodiment, a semiconductor device capable of improving characteristics is provided.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrodes, semiconductor members, semiconductor regions, insulating members, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode;
a third electrode including a first electrode portion, the first electrode portion being provided between the first electrode and the second electrode in a first direction from the first electrode to the second electrode;
a semiconductor member; and
a first insulating member,
at least a part of the first insulating member being provided between the third electrode and the semiconductor member,
the semiconductor member including a first semiconductor region and a second semiconductor region,
the first semiconductor region including Alₓ₁Ga₁₋ₓ₁N (0≤x1<1),
the first semiconductor region including a first partial region, a second partial region, a third partial region, a fourth partial region, and a fifth partial region,
a second direction from the first partial region to the first electrode crossing the first direction,
a direction from the second partial region to the second electrode being along the second direction,
a direction from the third partial region to the first electrode portion being along the second direction,
a fourth position in the first direction of the fourth partial region being between a first position in the first direction of the first partial region and a third position in the first direction of the third partial region,
a fifth position in the first direction of the fifth partial region being between the third position and a second position in the first direction of the second partial region,
the second semiconductor region including Alₓ₂Ga₁₋ₓ₂N (x1<x2≤1),
the second semiconductor region including a first semiconductor portion and a second semiconductor portion,
a direction from the fourth partial region to the first semiconductor portion being along the second direction,
a direction from the fifth partial region to the second semiconductor portion being along the second direction,
at least a part of the first electrode portion being between the first semiconductor portion and the second semiconductor portion in the first direction,
the second semiconductor region including a first semiconductor face and a second semiconductor face, the second semiconductor face facing the first semiconductor region, the second semiconductor face being between the first semiconductor region and the first semiconductor face in the second direction,
the third partial region includes a first portion and a second portion,
a first portion position of the first portion in the first direction being between the fourth position and a second portion position of the second portion in the first direction,
the first portion including a first face facing the first electrode portion in the second direction,
the second portion including a second face facing the first electrode portion in the second direction,
a first distance along the second direction between the first face and the second semiconductor face being shorter than a second distance along the second direction between the second face and the second semiconductor face,
the fourth partial region including a facing portion facing the first electrode portion in the first direction,
the first portion and the facing portion not including a p-type impurity, or a first concentration of the p-type impurity in the first portion is not less than 0.2 times and not more than 5 times a facing portion concentration of the p-type impurity in the facing portion.

2. The semiconductor device according to claim 1, wherein
the second portion does not include the p-type impurity, or the first concentration is not less than 0.2 times and not more than 5 times a second concentration of the p-type impurity in the second portion.

3. The semiconductor device according to claim 2, wherein
the second concentration is less than 1×10¹⁷ cm⁻³.

4. The semiconductor device according to claim 1, wherein
the first concentration is less than 1×10¹⁷ cm⁻³.

5. The semiconductor device according to claim 1, further comprising:
a first compound member including Al_{z1}Ga_{1-z1}N (x2<z1≤1),
at least a part of the first compound member being provided between the facing portion and the first insulating member, between the first portion and the first insulating member, and between the second portion and the first insulating member.

6. The semiconductor device according to claim 1, wherein
the first distance is less than 75 nm, and
the second distance is 100 nm or more.

7. The semiconductor device according to claim 1, wherein
the first distance is equal to or less than ½ of the second distance.

8. The semiconductor device according to claim 1, wherein
the first portion faces a first end of the first electrode portion on a side of the first electrode, and
the second portion faces a second end of the first electrode portion on a side of the second electrode.

9. The semiconductor device according to claim 1, wherein
the first face is aligned along the first direction, and
the second face is aligned along the first direction.

10. The semiconductor device according to claim 1, wherein
at least one of the first face or the second face is inclined with respect to the first direction.

11. The semiconductor device according to claim 1, wherein
a distance between the first electrode and the third electrode along the first direction is shorter than a distance between the third electrode and the second electrode along the first direction.

12. The semiconductor device according to claim 1, wherein
the third partial region includes a first step between the first portion and the second portion.

13. The semiconductor device according to claim 1, wherein
the third partial region further includes a third portion,
a third portion position in the first direction of the third portion is between the first portion position and the second portion position,
the third portion includes a third face facing the first electrode portion in the second direction, and
a third distance along the second direction between the third face and the first semiconductor face is between the first distance and the second distance.

14. The semiconductor device according to claim 13, wherein
the third portion does not include the p-type impurity, or the first concentration is not less than 0.2 times and not more than 5 times a third concentration of the p-type impurity in the third portion.

15. The semiconductor device according to claim 13, wherein
the third partial region includes a second step between the third portion and the second portion.

16. The semiconductor device according to claim 15, wherein
the third partial region includes one or more steps provided between the second step and the second portion.

17. The semiconductor device according to claim 1, wherein
the p-type impurity includes at least one selected from the group consisting of Mg, Zn, and Be.

18. The semiconductor device according to claim 1, wherein
the facing portion includes a first side face that faces the first electrode portion, and
a first angle between the first side face and the first face is not less than 80 degrees and not more than 100 degrees.

19. The semiconductor device according to claim 1, wherein
the fifth partial region includes a second side face that faces the first electrode portion in the first direction, and
a second angle between the second side face and the second face is not less than 80 degrees and not more than 100 degrees.

20. The semiconductor device according to claim 1, further comprising a second insulating member,
the second insulating member including a first insulating portion and a second insulating portion,
the first insulating portion being between the first semiconductor portion and a part of the first insulating member in the second direction, and
the second insulating portion being between the second semiconductor portion and another part of the first insulating member in the second direction.
